(19) United States
(12) Patent Application Publication
(10) Pub. No.: US 2002/0041028 A1
(43) Pub. Date: Apr. 11, 2002

(54) Method for forming damascene interconnection of semiconductor device and damascene interconnection fabricated thereby

(76) Inventors: Seung-Man Choi, Osan-shi (KR); Ki-Chul Park, Seoul (KR); Hyeon-Deok Lee, Seoul (KR)

Correspondence Address: JONES VOLENTINE, L.L.C., Suite 150, 12200 Sunrise Valley Drive, Reston, VA, 20191, US

(21) Appl. No.: 09/783,043

(22) Filed: Feb. 15, 2001

(30) Foreign Application Priority Data
Oct. 9, 2000 (KR) 2000-59302

(51) Int. Cl. H01L 21/4763; H01L 21/44; H01L 23/48; H01L 23/52; H01L 29/40

(52) U.S. Cl. 257/751; 257/753; 438/627; 438/643; 438/653; 438/927; 257/762; 438/687; 257/765; 257/773; 257/774; 438/688; 438/629; 438/637; 438/640

(57) ABSTRACT

A method for forming a damascene interconnection. After forming an insulating layer on a semiconductor substrate, the insulating layer is patterned and etched to form an opening. A barrier layer is formed on an entire surface of a resulting structure where the opening is formed. A seed layer is formed on at least on a sidewall of the opening on which the barrier layer is formed, and on a top surface of the insulating layer, using an ionized physical vapor deposition (PVD) apparatus having a target to which a power for making plasma is applied, and a chuck to which a radio frequency (RF) bias for accelerating ions is applied. When the seed layer is formed using an ionized PVD process, the power and bias are controlled to resputter an initial seed layer formed on a bottom of the opening. The resputtered seed layer is redeposited on the sidewall of the opening, forming a seed layer with a good step coverage characteristic on the sidewall. The barrier layer on the bottom of the opening is selectively removed to reduce a contact resistance.

This application is a counterpart of, and claims priority to, Korean Patent Application No. 2000-59302, filed on Oct. 9, 2000, the contents of which are herein incorporated by reference in their entirety.

### BACKGROUND OF THE INVENTION

1. Field of the Invention

The present invention generally relates to a method for fabricating a semiconductor device and a semiconductor device fabricated thereby. More specifically, the present invention is directed to a method for forming a damascene interconnection of a semiconductor device and a damascene interconnection fabricated thereby.

2. Description of the Related Art

As semiconductor devices become smaller and more densely integrated, the need for a low resistance interconnection between device elements has become apparent. The most widely used connection method is to form a metal interconnection using copper. As compared to other conventional interconnection materials, such as aluminum or tungsten, copper has a lower resistivity and a higher resistance to electro-migration.

A drawback to using copper, however, is that it is difficult to apply a patterning process by means of a dry etching technique. Therefore, copper interconnections are formed by a damascene process. The damascene process comprises the following general steps.

An opening (e.g., via hole or groove) is formed in an insulating layer. Then, a planarly etching process is performed after a copper layer is formed to fill the opening. Generally, an electroplating technique is used to form the copper layer. In order to form the copper layer, it is necessary to initially form a thin conductive layer (i.e., seed layer) that enables a current to flow. And, in order to fill the opening with the copper without voids, it is necessary to form a continuous seed layer on a sidewall of the opening. As a result, the deposition characteristics of the seed layer have a great influence on the resulting characteristics of the copper interconnection layer.

Conventionally, the seed layer is formed using a physical vapor deposition (PVD) technique. As semiconductor devices become more highly integrated, the pattern size is reduced and the aspect ratio increases, thereby requiring better step coverage characteristics. Accordingly, an ionized PVD process is used in which particles in a plasma are ionized and deposited. In the ionized PVD process, the ionized particles are accelerated toward a semiconductor substrate by a plasma sheath potential and the ionized particles are thereafter deposited on a semiconductor substrate. A bias is applied to the semiconductor substrate, so that the directional and acceleration characteristics of the deposition become greater to enhance the step coverage characteristic of the copper seed layer. Such an ionized PVD process is carried out using a conventional ionized PVD apparatus shown in FIG. 1 and FIG. 2.

FIG. 1 shows a PVD apparatus using a flat plate type target. A target 10 corresponding to a cathode is arranged at an upper part of a process chamber 27. The target 10 is coupled to a power source 20 that applies a power so as to form plasma 17. A chuck 12 corresponding to an anode is arranged at a lower part of the process chamber 27, opposite to the target 10. A semiconductor substrate (not shown) is placed on a top surface of the chuck 12. The chuck 12 is coupled to a radio frequency (RF) power source 25 that applies a bias so as to accelerate ions toward the semiconductor substrate. In the process chamber 27, a coil 15 is used to ionize particles in the plasma 17. Although not shown in the figure, a power source applying an RF power is coupled to the coil 15.

FIG. 2 shows a PVD apparatus using a cylindrical target. A cylindrical target 30 is arranged at an upper part of a process chamber 45. The target 30 is coupled to a power source 40 that applies a power so as to form plasma 37. A chuck 32 is arranged at a lower part of the process chamber 45, opposite to the target 30. The chuck 32 is coupled to an RF power source 42 that applies a bias so as to accelerate ions toward the semiconductor substrate. If the power is applied to the target 30, the plasma 37 is formed in the cylindrical target 30. Thus, the density of the plasma 37 in FIG. 2 is higher than that of the plasma 17 formed in the process chamber 27 of FIG. 1. Without applying an RF power, the particles in the plasma 37 can be ionized.

Unfortunately, if a copper seed layer is formed using a conventional ionized PVD process, the profile of the copper seed layer is degraded on a sidewall of an opening, as shown in FIG. 3, and an overhang phenomenon occurs. FIG. 3 is a cross-sectional view showing a copper seed layer profile that is formed using a conventional ionized PVD process. After forming an opening 55 in an insulating layer 52 formed on a semiconductor substrate 50, a copper seed layer 58 is formed using the ionized PVD process. Since copper ions in plasma are accelerated toward the semiconductor substrate 50 during the ionized PVD process, they proceed in a fairly straight or linear path. Accordingly, the copper seed layer 58 has a good profile as viewed along a horizontal plane (being perpendicular to the path of the accelerated ions), i.e., a top surface 57a of the insulating layer 52 and a bottom surface 57c of the opening 55. However, the copper seed layer 58 has a degraded profile as viewed along a vertical plane (being parallel to the path of the accelerated ions), i.e., a sidewall 57b of the opening 55.

In this case, the thickness of the copper seed layer 58 is not sufficient on the sidewall 57b of the opening 55, and the copper seed layer 58 is agglomerated. Moreover, an overhang phenomenon occurs at the opening 55 as shown in FIG. 3, such that the opening 55 is not uniformly filled in the subsequent process to form a copper layer using the electroplating technique, thereby creating voids.

### SUMMARY OF THE INVENTION

In view of the above, it is an object of the present invention to provide a method of forming a damascene interconnection having a copper layer which is filled without voids by forming a seed layer having an improved step coverage on a sidewall of an opening.

It is another object of the present invention to provide a method of forming a damascene interconnection with low contact resistance by selectively removing a barrier layer formed on a lower conductive.

It is further object of the present invention to provide a damascene interconnection structure which has a copper layer filled without voids, and which has a low contact resistance.

According to an aspect of the present invention, there is provided a method of forming a damascene interconnection. First, an insulating layer is formed on a semiconductor substrate. The insulating layer is patterned and etched to form an opening which exposes a predetermined region of the substrate. A seed layer is formed to cover a sidewall of the opening and a top surface of the insulating layer. A copper layer is formed on the seed layer, filling the opening. Then, the copper layer is planarly etched down to the top surface of the insulating layer.

Preferably, the seed layer is formed using an ionized physical vapor deposition (PVD) apparatus that has a target corresponding to a cathode to which a power for making plasma is applied, and a chuck corresponding to an anode to which a radio frequency (RF) bias for accelerating ions is applied. The chuck is positioned opposite to the target.

Preferably, the seed layer is deposited on the resulting structure where the opening is formed. And, the seed layer on a bottom of the opening is resputtered, thereby being redeposited on the sidewall of the opening.

According to another aspect of the present invention, there is provided a method of forming a damascene interconnection. First, an insulating layer is patterned to form an opening which exposes a predetermined region of a semiconductor substrate. Using an ionized PVD process, a seed layer is formed on an entire surface of the resulting structure where the opening is formed. Forming the seed layer is divided into two steps. In a first step, the seed layer on a bottom of the opening is resputtered, thereby being redeposited on a sidewall of the opening. Thus, the seed layer remaining on the bottom is relatively thinner than that on the sidewall. In a second step, another seed layer is formed on the entire surface of the resulting structure where the opening is formed. A copper layer is formed on the entire surface to fill the opening, and then is planarly etched down to a top surface of the insulating layer.

Preferably, the seed layer is formed using an ionized physical vapor deposition (PVD) apparatus that has a target corresponding to a cathode to which a power for making plasma is applied, and a chuck corresponding to an anode to which a radio frequency (RF) bias for accelerating ions is applied. The chuck is positioned opposite to the target.

Preferably, a power for making plasma in the second step is relatively higher than that for making plasma in the first step, and an RF bias in the second step is relatively lower than that in the first step.

The damascene interconnection structure of this invention includes a semiconductor substrate, an insulating layer formed on the substrate, an opening penetrating the insulating layer to expose a predetermined region of the substrate, and a seed layer formed at least on a sidewall of the opening.

### BRIEF DESCRIPTION OF THE DRAWINGS

FIG. 1 is a schematic diagram showing a conventional ionized physical vapor deposition (PVD) apparatus using a flat target;

FIG. 2 is a schematic diagram showing a conventional ionized physical vapor deposition (PVD) apparatus using a cylindrical target;

FIG. 3 is a cross-sectional view of a seed layer which is formed using the PVD apparatus of FIG. 1 or FIG. 2;

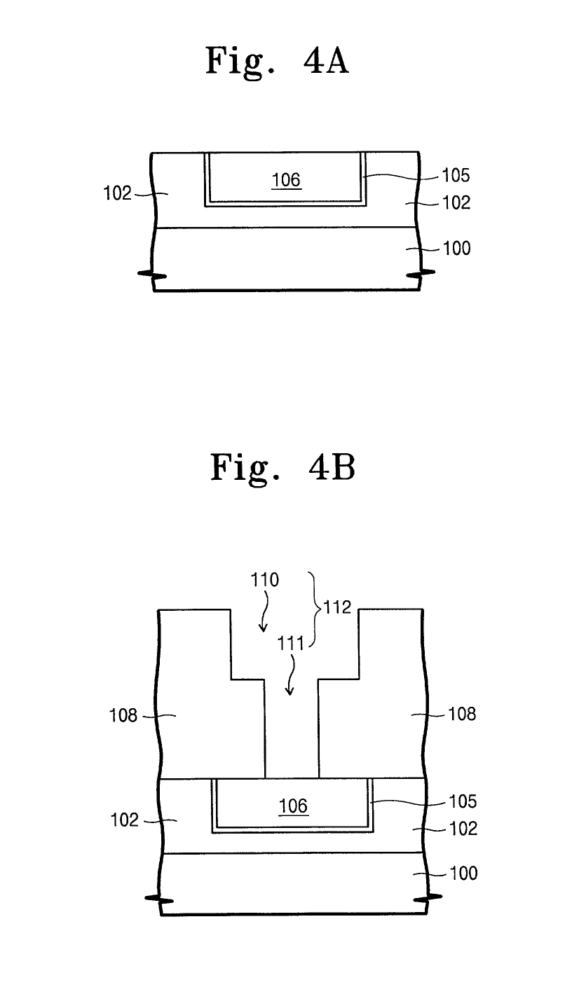

FIG. 4A through FIG. 4F are cross-sectional views for explaining a method of forming a damascene interconnection in accordance with a first embodiment of the present invention;

FIG. 5A through FIG. 5C are cross-sectional views for explaining a method of forming a damascene interconnection in accordance with a second embodiment of the present invention;

FIG. 6A through FIG. 6C are cross-sectional views for explaining a method of forming a damascene interconnection in accordance with a third embodiment of the present invention;

FIG. 7A shows a scanning electron microscopy (SEM) photograph of a copper seed layer which is formed using a prior art PVD technique;

FIG. 7B is an enlarged view of a portion of FIG. 7A;

FIG. 8A shows a SEM photograph of a copper seed layer in accordance with the preferred embodiment of the present invention; and

FIG. 8B is an enlarged view of a portion of FIG. 8A.

### DESCRIPTION OF THE PREFERRED EMBODIMENT

The present invention will now be described more fully hereinafter with reference to the accompanying drawings, in which preferred embodiments of the invention are shown. This invention may, however, be embodied in different forms and should not be constructed as limited to the embodiments set forth herein. Rather, these embodiments are provided so that this disclosure will be thorough and complete, and will fully convey the scope of the invention to those skilled in the art. Like numbers refer to like elements throughout.

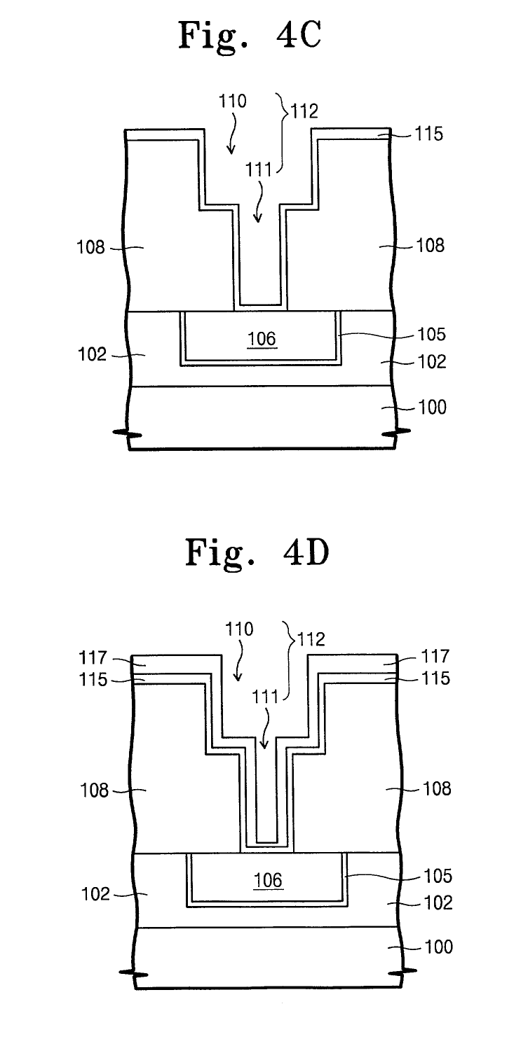

FIG. 4A through FIG. 4F are cross-sectional views showing a method of forming a copper interconnection of a dual damascene structure, in accordance with a first embodiment of the present invention.

In FIG. 4A, a first insulating layer 102 and a first metal interconnection 106 are formed on a semiconductor substrate 100. The first metal interconnection 106 is formed in the first insulating layer 102, using a conventional technique such as a damascene process. Preferably, the first metal interconnection 106 is made of, for example, copper and a barrier layer 105 is formed between the first insulating layer 102 and the first metal interconnection 106.

In FIG. 4B, a second insulating layer 108 is formed on the first insulating layer 102 including the first metal interconnection 106. Using a two step photolithographic process, the second insulating layer 108 is patterned to form an opening 112 having a dual damascene structure. For example, a photoresist pattern (not shown) for forming a groove is formed on the second insulating layer 108. Using the photoresist pattern for forming the groove as an etching mask, a top surface of the second insulating layer 108 is etched to form a groove 110. After removing the photoresist pattern, a second photoresist pattern (not shown) for forming a via hole is formed on an entire surface of the resulting structure where the groove 110 is formed. Using this second photoresist pattern for forming the via hole as an etching mask, the second insulating layer 108 is etched to form a via hole 111 such that a predetermined region of the first metal interconnection 106 is exposed. Thus, an opening 112 is formed having a dual damascene structure composed of the via hole 111 and the groove 110.

After forming the opening 112, preferably, a cleaning process is performed to remove an oxide layer that is formed on an exposed surface of the first metal interconnection 106. In the cleaning process, the oxide layer is removed by a radio frequency (RF) etching technique using argon plasma. Alternatively, the oxide layer is deoxidized using hydrogen gas.

In FIG. 4C, a barrier layer 115 is formed on an entire surface of the resulting structure where an opening 112 is formed. If the metal interconnection is made of copper, the barrier layer 115 serves to prevent copper particles from diffusing toward a second insulating layer 108. The barrier layer is a single or multiple layer made of one selected from a group consisting of, for example, Ti, TiN, W, WN, Ta, TaN, and all combinations thereof.

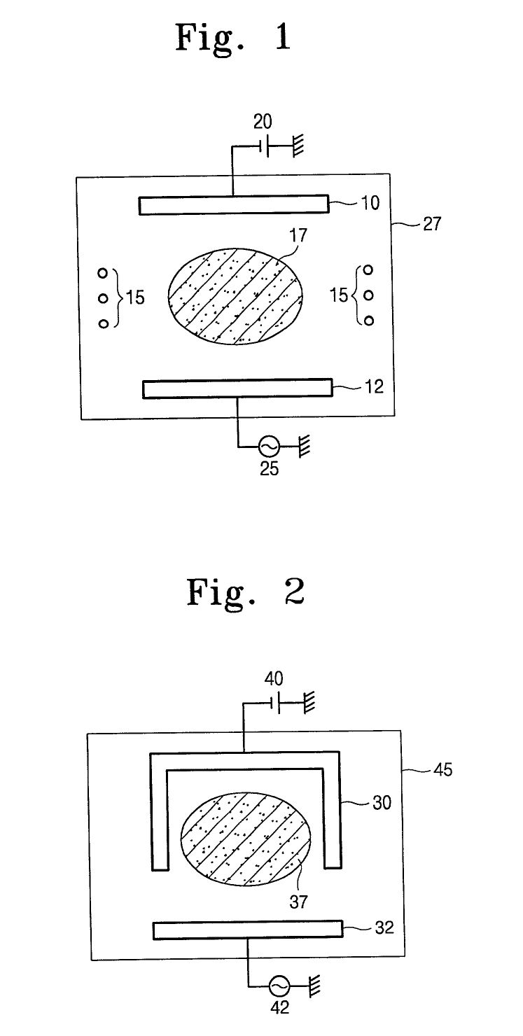

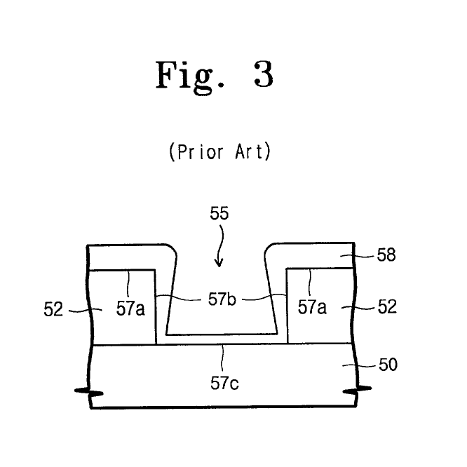

In FIG. 4D, as a conductive layer, a seed layer 117 for forming a copper layer is formed on the barrier layer 115. Preferably, the seed layer 117 is made of one selected from a group consisting of, for example, copper, aluminum, and a combination thereof. The ionized PVD process is performed using, for example, a PVD apparatus shown in FIG. 1 and FIG. 2.

Now, a process for forming the seed layer 117 of this invention using a PVD apparatus shown in FIG. 2 will be described hereinafter. A substrate 100 over which a barrier layer 115 is formed is loaded on the chuck 32 in a process chamber 45. A processing gas (e.g., argon gas) is supplied into the process chamber 45, and a power (e.g., DC power) for making plasma is applied to the target 30. Ionized particles sputtered from the target 30 by the argon ions collide with particles in plasma 37. An RF bias for accelerating ions in the plasma 37 is applied to the chuck 32. The applied RF bias accelerates the direction and energy of the ions, improving the step coverage characteristic of the seed layer 117 and enhancing a resputtering phenomenon of the seed layer 117.

Variables of the ionized PVD process are controlled to optimize a profile of the seed layer 117 that is formed on the sidewall of the opening 112. In other words, the power for making plasma applied to the target 30 and the RF bias applied to the chuck 32 are controlled to form a continuous seed layer 117 having a sufficient thickness on the sidewall of the opening 112 and the top surface of the second insulating layer 108. Preferably, the initial seed layer 117 deposited on the bottom of the opening 112 is resputtered to be redeposited on the sidewall of the opening 112, improving the profile of the seed layer 117 that is formed on the sidewall of the opening 112. Thus, the seed layer 117 remaining on the bottom of the opening 112 is relatively thinner than that formed on the sidewall of the opening 112.

Hereinafter, the influence of the RF bias for accelerating the power for making plasma and ions upon formation of the seed layer 117 will now be described more fully. When a layer is formed using the ionized PVD process, deposition and etching techniques occur uniformly on a horizontal surface of a semiconductor substrate 100, since it is perpendicular to the path of the accelerated ions. On the other hand, the deposition speed on a sidewall, which is parallel to the path of the accelerated ions, is much lower than that on the horizontal surface. Moreover, the sidewalls are not normally subjected to etching techniques.

If the power for making plasma is reduced to slow down an etching speed, the deposition speed of the horizontal surface can be reduced without affecting the deposition speed of the sidewall. In particular, the deposition speed at the bottom of the opening 112 having a large aspect ratio is much lower in comparison with other horizontal surfaces. If the deposition speed of the sidewall is sufficiently reduced, the seed layer 117 formed on the bottom of the opening 112 is resputtered, and the seed layer 117 is sufficiently deposited on other horizontal surfaces. In this case, the profile of the seed layer 117 formed on the sidewall of the opening 112 can be improved because particles resputtered on the bottom of the opening 112 are redeposited on the sidewall thereof.

In FIG. 4E, a copper layer 120 to fill an opening 112 is formed on an entire surface of a semiconductor substrate 100 where a seed layer 117 is formed. Preferably, the copper layer 120 is formed using an electroplating technique. Since the continuous seed layer 117 having a sufficient thickness is formed on a sidewall of the opening 112, the electroplating technique makes it possible to fill the opening 112 with the copper layer 120 without voids. Finally, an annealing process is performed at a temperature of at least 200° C. to enhance cohesion between the barrier layer 115 and the copper layer 120.

In FIG. 4F, the barrier layer 115 and the copper layer 120 are planarly etched down to a top surface of a second insulating layer 108, forming a second metal interconnection 120a and a via hole 120b. The second metal interconnection 120a fills a groove 110, and the via hole 120b connects the second metal interconnection 120a to the first metal interconnection 106. The planarly etching technique uses, for example, a chemical mechanical polishing (CMP) technique.

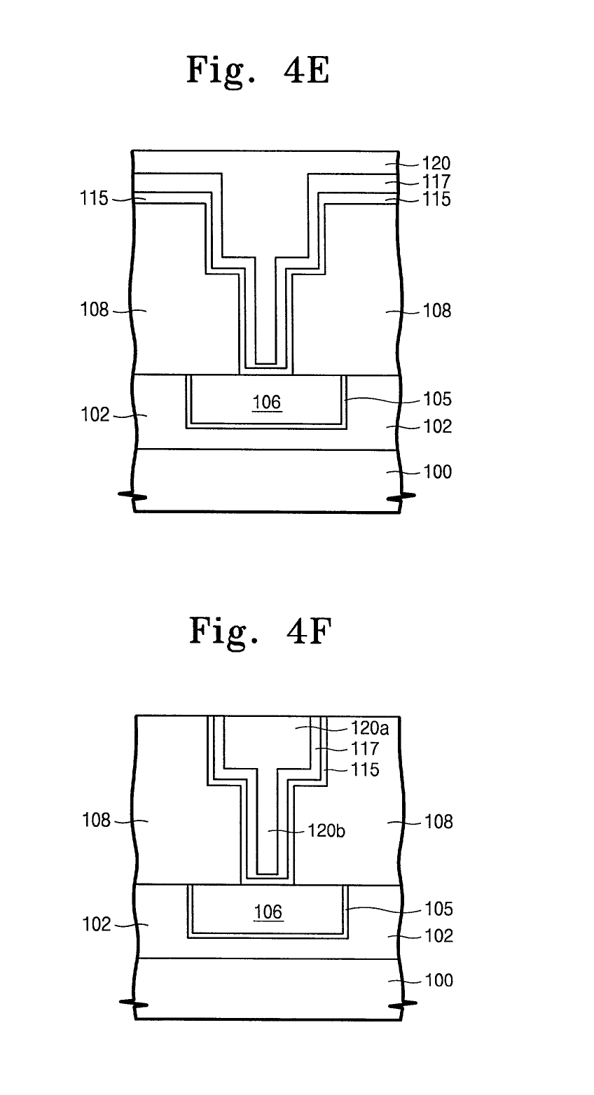

FIG. 5A through FIG. 5C are cross-sectional views for explaining a method for forming a copper interconnection of a dual damascene structure in accordance with a second embodiment of the present invention.

In FIG. 5A, a barrier layer 115 is formed on an entire surface of a resulting structure where an opening 112 is formed in a manner similar to that described with respect to the first embodiment of the present invention. A seed layer 130 is formed on the barrier layer 115 using an ionized PVD process. As described in the first embodiment, the ionized PVD process is performed using an ionized PVD apparatus shown in FIG. 1 or FIG. 2.

Variables of the ionized PVD process are controlled such that a seed layer 130 is formed only on a sidewall of the opening 112 and a top surface of a second insulating layer 108. More specifically, although a seed layer 130 is not formed on a bottom of a via hole 111, a continuous seed layer 130 is formed on a sidewall of the via hole 111, a bottom and a sidewall of a groove 110, and a top surface of the second insulating layer 130. To achieve this, the power for making plasma and an RF bias for accelerating ions are controlled to resputter the entire thickness of the seed layer 130 that is formed on the bottom of the opening 112. Since the seed layer 130 is not formed on the bottom of the opening 112 and resputtered particles are redeposited on a sidewall of the opening 130, the seed layer 130 is formed with a sufficient thickness on the sidewall.

Preferably, when the seed layer 130 on the bottom of the opening 112 is resputtered, the barrier layer 115 formed on the bottom of the opening 130 is also selectively removed to expose a predetermined region of a first metal interconnection 106. As a result, the barrier layer 115 and the seed layer 130 are formed on the sidewall of the opening 112 and the top surface of the second insulating layer 108, and a first metal interconnection 106 having an exposed structure is formed on the bottom of the opening 112. If the barrier layer 115 formed on the first metal interconnection 106 is removed, an interconnection having a low contact resistance can be formed. Also, the barrier layer 115 formed on the bottom of the opening 112 can be removed and a top surface of the first metal interconnection 106 can be etched. Thus, it is possible to skip a cleaning process for removing an oxide layer formed on a surface of the first metal interconnection 106 after forming the opening 112.

In FIG. 5B, a copper layer 133 is formed on an entire surface of a semiconductor substrate 100 where a seed layer 130 is formed, using an electroplating technique. Since a continuous seed layer 130 having a sufficient thickness is formed on a sidewall of an opening 112, the opening 112 is filled with the copper layer 133 without voids. Preferably, an annealing process is performed at a temperature of 200° C., stabilizing the copper layer 133 and enhancing cohesion between the barrier layer 115 and the copper layer 133. If grains grow between the copper layer 133 and a first metal interconnection 106 where the barrier layer 115 is removed during the annealing process, the contact resistance can become lower.

In FIG. 5C, the barrier layer 115 and the copper layer 133 are planarly etched down to a top surface of a second insulating layer 108, forming a second metal interconnection 133a and a via hole 133b connecting a first metal interconnection 106 to the second metal interconnection 133a.

According to such a second embodiment, a seed layer 112 having a good profile is formed on a sidewall of an opening 112, filling the opening 112 with a copper layer 133 without voids. And, a barrier layer 115 on a first metal interconnection 106 is removed to reduce a contact resistance in comparison with the first embodiment.

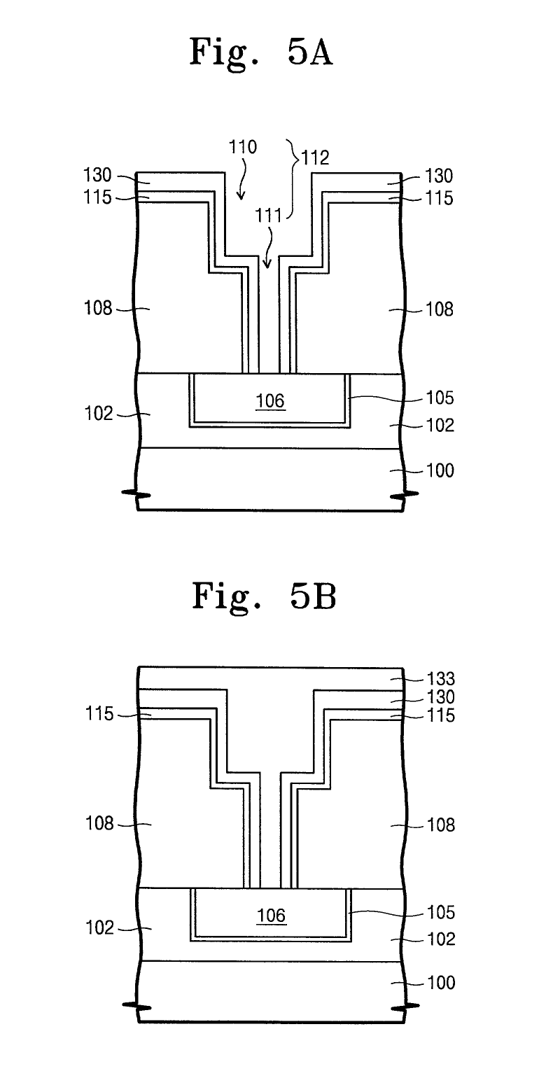

FIG. 6A through FIG. 6C are cross-sectional views for explaining a method for forming a copper interconnection of a dual damascene structure in accordance with a third embodiment of the present invention.

In FIG. 6A, a barrier layer 115 is formed on an entire surface of a resulting structure where an opening 112 is formed in a manner similar to that described with respect to the first embodiment. A seed layer 140 is formed on the barrier layer 115 by an ionized PVD process. As described in the first embodiment, the ionized PVD process is performed using an ionized PVD apparatus shown in FIG. 1 or FIG. 2.

The ionized PVD process is performed after removing the barrier layer 115 formed on a bottom of the opening 112. A seed layer 140 is additionally formed on an entire surface of a resulting structure where the opening 112 is formed. For example, a seed layer 140 is formed by an ionized PVD process that is composed of two steps. The first step of the ionized PVD process is performed on condition that the seed layer 140 on the bottom of the opening 112 is resputtered and the barrier layer 115 thereon is removed. Thus, a seed layer 140 is formed on a barrier layer 115 that remains on a sidewall of the opening 112 and a top surface of a second insulating layer 108, with the barrier layer 115 thereon removed. After the barrier layer 115 on the bottom of the opening 112 is removed and the seed layer 140 having a sufficient thickness to prevent an agglomeration phenomenon is formed on a sidewall thereof, a second step of the ionized PVD process is carried out. The deposition speed of the second step is higher than that of the first step, such that a resputtering phenomenon is reduced to additionally form a seed layer 140 on an entire surface of a resulting structure where an opening 112 is formed. That is, compared with the first step, a relatively higher power for making plasma and a relatively lower or equal RF bias are applied to perform the second step. So, on the bottom of the opening 112 where the barrier layer 115 is removed, the seed layer 140 is additionally formed to create a structure where the seed layer 140 is connected to the first metal interconnection 106.

In FIG. 6B, using an electroplating technique, a copper layer 143 is formed on an entire surface of a semiconductor substrate 100 where a seed layer 140 is formed. Since a seed layer 140 having a sufficient thickness is formed on a sidewall of an opening 112, the opening 112 can be filled with the copper layer 143 without voids. Similar to the second embodiment, if an annealing process is performed to grow grains between a first metal interconnection 106 and the copper layer 143, a contact resistance can become lower.

In FIG. 6C, a barrier layer 115 and a copper layer 143 are planarly etched down to a top surface of the second insulating layer 108, forming a second metal interconnection 143a and a via hole 143b. The via hole 143b connects a first metal interconnection 106 to the second metal interconnection 143a.

According to such a third embodiment, it is possible to fill an opening 112 with a copper layer 143 without voids and reduce a contact resistance, as mentioned in the second embodiment.

The ionized PVD process for improving the profile of the seed layer is performed at a low deposition speed. In comparison with the conventional manner, a power for making plasma decreases and an RF bias for accelerating ions increases. Therefore, the step coverage characteristic of the seed layer is improved while the deposition speed is reduced. Accordingly, after a seed layer having an enough thickness to prevent a discontinuity phenomenon is formed on the sidewall of the opening, the second step of the ionized PVD process is performed to form a seed layer at a faster speed than the first step. That is, compared with the first step, a relatively higher power for making plasma and a relatively lower or equal RF bias are applied to perform the second step.

If a seed layer is formed using such an ionized PVD process that is composed of two steps (a first step is to improve a sidewall profile of a seed layer, and a second step is to additionally form a seed layer), a seed layer having a good profile can be formed on the sidewall of the opening. And, it is possible to prevent a low deposition speed from lowering productivity.

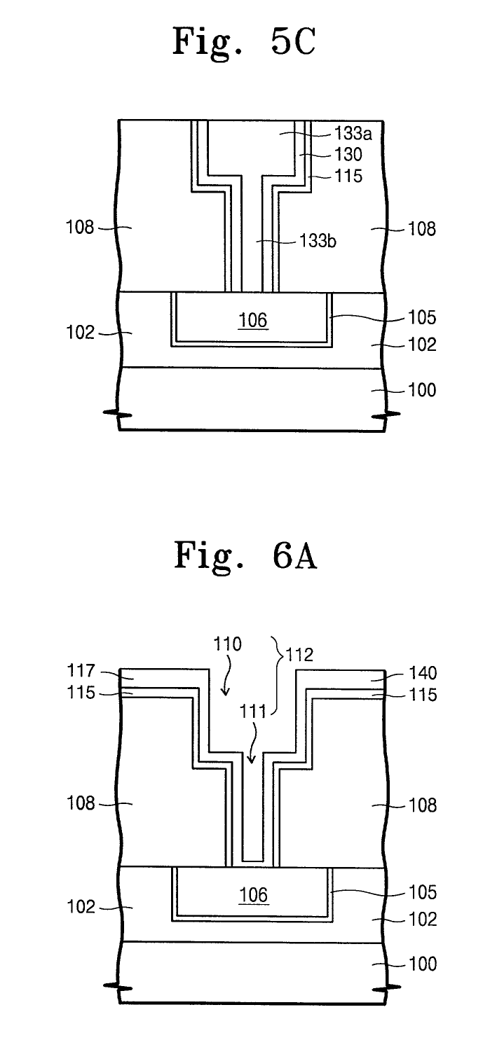

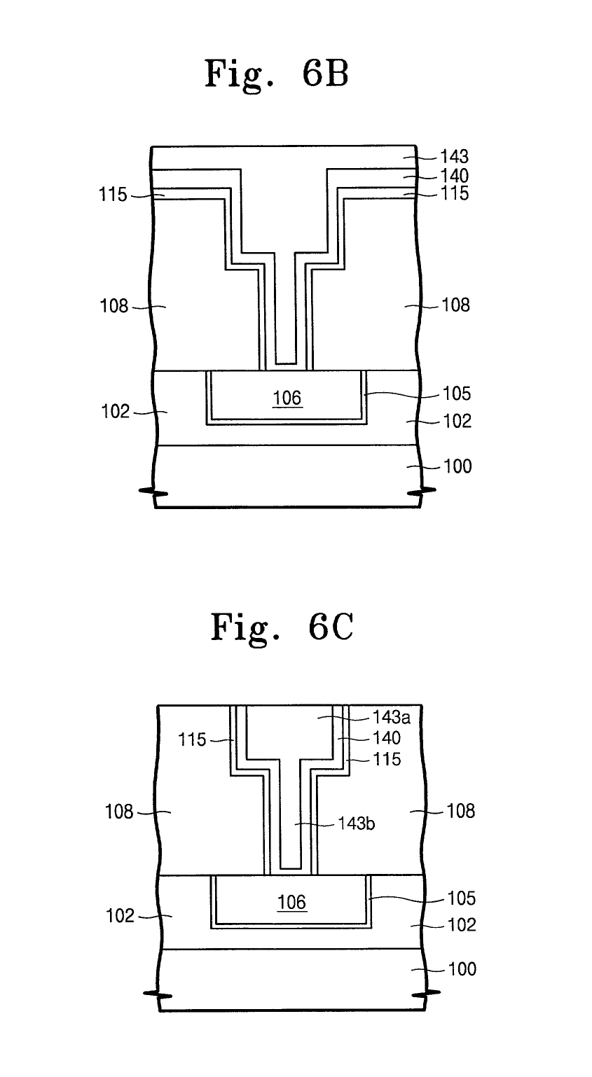

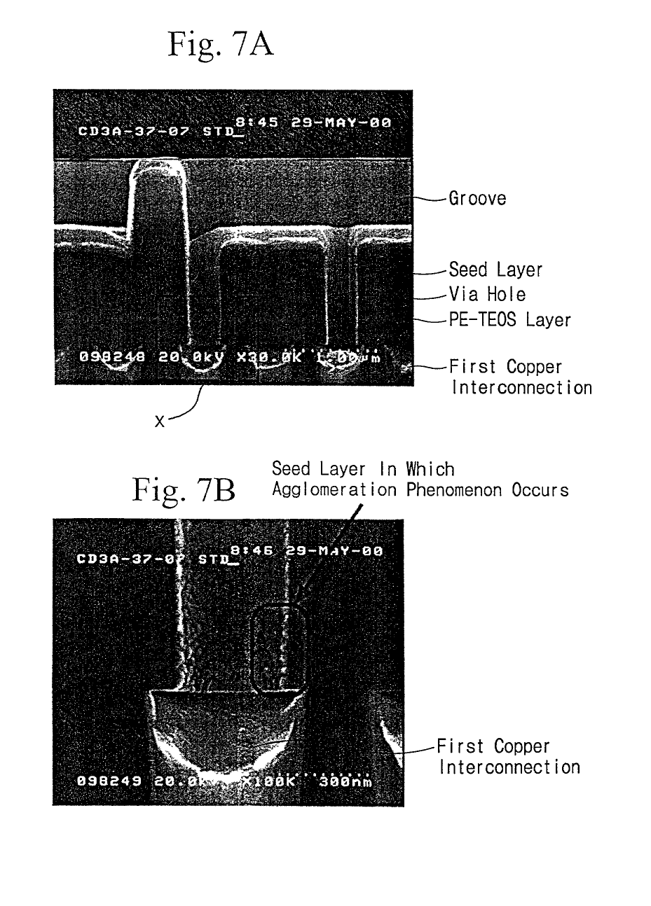

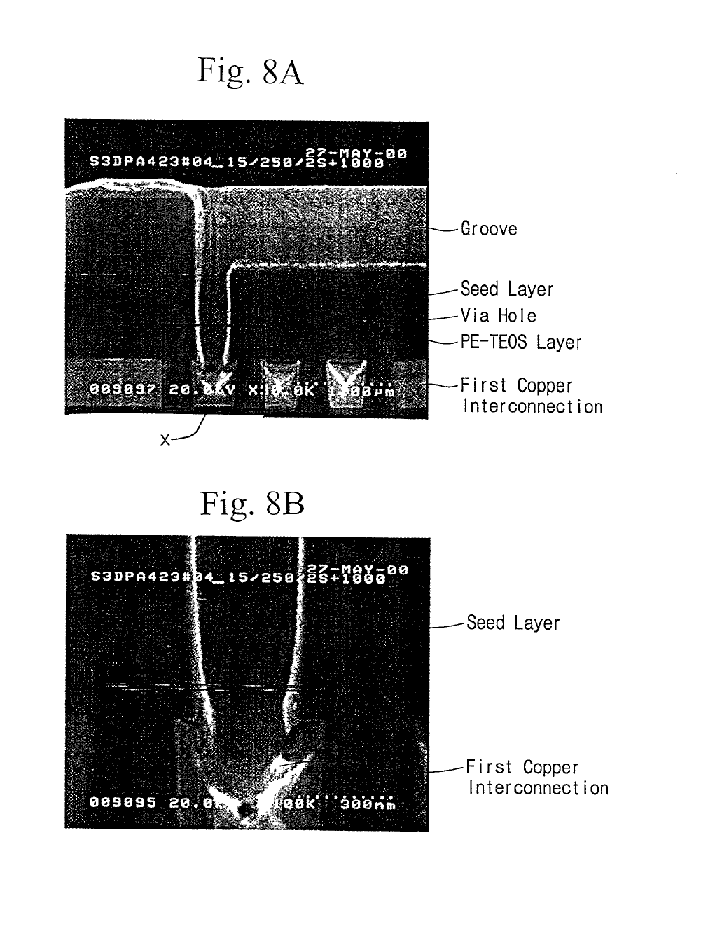

Now, the results of comparing the conventional techniques with the preferred embodiment of the invention will be described hereinafter with reference to FIG. 7 and FIG. 8.

FIG. 7A shows a scanning electron microscopy (SEM) photograph of a copper seed layer which is formed using a prior art PVD technique, and FIG. 7B is an enlarged view of a portion ‘x’ of FIG. 7A. FIG. 8A shows a SEM photograph of a copper seed layer in accordance with the preferred embodiment of the present invention, and FIG. 8B is an enlarged view of a portion ‘x’ of FIG. 8A.

A test for comparing profiles of the seed layers (formed according to prior art and the preferred embodiment of the invention) was performed as follows. After forming a plasma enhanced tetraethylorthosilicate (PE-TEOS) layer having a thickness of 4500 Å on a semiconductor substrate, a first copper interconnection was formed using a damascene technique. As an interlayer insulating layer, a PE-TEOS layer having a thickness of 18000 Å was formed on the insulating layer including the first copper interconnection. The interlayer insulating layer was patterned to form a groove having a depth of 7000 Å and a via hole having a depth of 11000 Å. As a barrier layer, a TaN layer having a thickness of 450 Å was formed on the entire surface of the resulting structure where the groove and the via hole were formed. A copper seed layer having a thickness of 1500 Å was formed on the barrier layer using an ionized PVD process, which was performed by a PVD apparatus shown in FIG. 2.

The ionized PVD process for forming a copper seed layer according to the prior art was performed on condition that a DC power (30 kW) for making plasma was applied to a target and an RF bias was not applied to the chuck. The copper seed layer according to the present invention was formed using an ionized PVD process that was composed of two steps. The first step was to form a copper seed layer having a thickness of 500 Å on condition that a DC power (15 kW) for making plasma was applied to a target and an RF bias (250 W) was applied to the chuck. The second step was to additionally form a copper layer having a thickness of 1000 Å on condition that a DC power (30 kW) for making plasma was applied to the target and an RF bias was not applied to the chuck, which is similar to the prior art.

As shown in FIG. 7A and FIG. 7B, if a seed layer is formed according to the prior art, an agglomeration phenomenon of the seed layer occurs on the sidewall of the via hole. This is because the thickness of the copper seed layer deposited on the sidewall of the via hole is not sufficient. A discontinuous seed layer thus results from the agglomeration phenomenon, forming a void in the via hole during a process for forming a copper layer using an electroplating technique.

By contrast, as shown in FIG. 8A and FIG. 8B, if a seed layer is formed according to the present invention, a continuous copper seed layer is formed on a sidewall of a via hole. Accordingly, using an electroplating technique, a copper layer is formed to fill the via hole without voids. And, a barrier layer on a bottom of the via hole is removed to expose a first copper interconnection.

Based upon the above results, it is confirmed that a continuous seed layer can be formed on a sidewall of a via hole using a method for forming a seed layer according to the present invention. In other words, during an ionized PVD process for forming a seed layer, a DC power for making plasma and a substrate bias are controlled to form a seed layer with a good step coverage characteristic on a sidewall of an opening.

As mentioned so far, since a seed layer having a good profile can be formed on a sidewall of an opening using an ionized PVD process, the opening can be filled with a copper layer without voids. And, since a barrier layer on a bottom of a via hole can selectively be removed during a process for forming a seed layer, a contact resistance between a lower metal interconnection and a via hole is reduced to enhance the electrical characteristics of the semiconductor devices.

In the drawings and specification, there have been disclosed typical preferred embodiments of the invention and, although specific terms are employed, they are used in a generic and descriptive sense only and not for purpose of limitation, the scope of the invention being set forth in the following claims.

What is claimed is:

1. A method for forming a damascene interconnection comprising:
forming an insulating layer on a semiconductor substrate;
patterning and etching the insulating layer to form an opening exposing a predetermined region of the semiconductor substrate; and
forming a seed layer covering only a sidewall of the opening and a top surface of the insulating layer,
wherein the seed layer is formed by depositing the seed layer on an entire surface of a resulting structure where the opening is formed, and resputtering the seed layer resident on a bottom of the opening.

2. The method of claim 1, wherein the seed layer is formed using an ionized physical vapor deposition (PVD) apparatus that has a target corresponding to a cathode to which a power for making plasma is applied, and a chuck, positioned opposite to the target, corresponding to an anode to which a radio frequency (RF) bias for accelerating ions is applied.

3. The method of claim 1, wherein the seed layer is made of one selecting from a group consisting of copper, aluminum, and a combination thereof.

4. The method of claim 1, wherein after forming the seed layer, the method further comprising steps of:
forming a copper layer on the seed layer to fill the opening; and
planarly etching the copper layer and the seed layer down to a top surface of the insulating layer.

5. The method of claim 4, wherein the copper layer is formed using an electroplating technique.

6. The method of claim 1, wherein before forming the seed layer, the method further comprising a step of forming a barrier layer on the entire surface of the resulting structure where the opening is formed.

7. The method of claim 6, wherein the barrier layer on the bottom of the opening is selectively removed when the seed layer is formed.

8. The method of claim 6, wherein the barrier layer is made of one selected from a group consisting of Ti, TiN, W, WN, Ta, and TaN.

9. The method of claim 1, wherein the opening comprises a via hole exposing a predetermined region of the substrate, and a groove.

10. A method for forming a damascene interconnection comprising:
forming an insulating layer on a semiconductor substrate;
patterning and etching the insulating layer to form an opening exposing a predetermined region of the semiconductor substrate; and
forming an initial seed layer on an entire surface of a resulting structure where the opening is formed, using an ionized PVD process;
resputtering, in a first step, the initial seed layer on a bottom of the opening to be redeposited on a sidewall of the opening such that the initial seed layer remaining on the bottom of the opening is relatively thinner than that on the sidewall thereof, and
forming, in a second step, an additional seed layer on the entire surface of the resulting structure where the opening is formed.

11. The method of claim 10, wherein the ionized PVD process is performed using an ionized physical vapor deposition (PVD) apparatus that has a target corresponding to a cathode to which a power for making plasma is applied, and a chuck, positioned opposite to the target, corresponding to an anode to which a radio frequency (RF) bias for accelerating ions is applied.

12. The method of claim 11, wherein the power in the second step is higher relative to that in the first step, and the RF bias in the second step is equal to or lower relative to that in the first step.

13. The method of claim 12, wherein the step of resputtering the initial seed layer on the bottom of the opening is performed until the layer underlying the initial seed layer is exposed.

14. The method of claim 10, wherein after forming the additional seed layer, the method further comprising the steps of:
forming a copper layer on the additional seed layer to fill the opening; and
planarly etching the copper layer and the additional seed layer down to a top surface of the insulating layer.

15. A damascene interconnection structure comprising:
a semiconductor substrate;
an opening penetrating the insulating layer to expose a predetermined region of the semiconductor substrate; and
a seed layer formed on a sidewall and a bottom of the opening, and the seed layer on the sidewall of the opening is relatively thicker than that on the bottom thereof.

16. The damascene interconnection structure of claim 15, further comprising a copper layer filling the opening in which the seed layer is formed.

17. The damascene interconnection structure of claim 15, further comprising a barrier layer formed between the sidewall of the opening and the seed layer.

18. The damascene interconnection structure of claim 17, wherein the barrier layer on a bottom of the opening is selectively removed.

19. The damascene interconnection structure of claim 15, wherein the opening is composed of a via hole exposing a predetermined region of the semiconductor substrate, and a groove.
